(19) United States
(12) Patent Application Publication
(10) Pub. No.: US 2015/0184311 A1
(43) Pub. Date: Jul. 2, 2015

(54) LINING FOR SURFACES OF A REFRACTORY CRUCIBLE FOR PURIFICATION OF SILICON MELT AND METHOD OF PURIFICATION OF THE SILICON MELT USING THAT CRUCIBLE(S) FOR MELTING AND FURTHER DIRECTIONAL SOLIDIFICATION

(71) Applicant: Silicor Materials Inc., San Jose, CA (US)

(72) Inventors: Alain Turenne, Kitchener (CA); Christain Alfred, Brampton (CA)

(21) Appl. No.: 14/409,534

(22) PCT Filed: Jun. 25, 2013
(86) PCT No.: PCT/US2013/047601

§ 371 Date: Dec. 19, 2014

Related U.S. Application Data
(60) Provisional application No. 61/663,911, filed on Jun. 25, 2012.
(60) Provisional application No. 61/663,918, filed on Jun. 25, 2012.

(51) Int. Cl. C30B 11/00; C01B 33/037; C30B 29/06

(52) U.S. Cl. CPC C30B 11/002; C30B 29/06; C01B 33/037

(57) ABSTRACT

A crucible for molten silicon comprises at least one refractory material having an inner surface and a lining deposited onto the inner surface, the lining comprising colloidal silica. A method for silicon purification comprises melting a first silicon in an interior of a melting crucible to provide a first molten silicon, the melting crucible comprising a first refractory material having at least one first inner surface defining the melting crucible interior, directionally solidifying the first molten silicon in a directional solidification mold to provide a second silicon, the directional solidification mold comprising a second refractory material having at least one second inner surface defining a mold interior, and coating at least a portion of at least one of the first inner surface and the second inner surface with a lining comprising colloidal silica.

### CROSS-REFERENCE TO RELATED APPLICATIONS

This application claims the benefit of priority to U.S. Provisional Application No. 61/663,911, filed Jun. 25, 2012, and claims the benefit of priority to U.S. Provisional Application No. 61/663,918, filed Jun. 25, 2012, which are herein incorporated by reference in their entirety.

### BACKGROUND

Solar cells can be a viable energy source by utilizing their ability to convert sunlight to electrical energy. Silicon is a semiconductor material used in the manufacture of solar cells; however, a limitation of silicon use relates to the cost of purifying it to solar grade (SG).

Several techniques used to purify silicon for solar cells are known. Most of these techniques operate on the principle that while silicon is solidifying from a molten solution, undesirable impurities can tend to remain in the molten solution. For example, the float zone technique can be used to make monocrystalline ingots, and uses a moving liquid zone in a solid material, moving impurities to edges of the material. In another example, the Czochralski technique can be used to make monocrystalline ingots, and uses a seed crystal that is slowly pulled out of a solution, allowing the formation of a monocrystalline column of silicon while leaving impurities in the solution. In yet another example, the Bridgeman or heat exchanger techniques can be used to make multicrystalline ingots, and use a temperature gradient to cause directional solidification.

### SUMMARY

In view of current energy demands and supply limitations, the present inventors have recognized a need for a more cost efficient way of purifying metallurgical grade (MG) silicone (or any other silicon having a greater amount of impurities than solar grade) to solar grade silicon. The present disclosure describes a vessel, such as a crucible made from a refractory material, such as alumina, which can be used for purification of silicon, such as via directional solidification. Silicon can be melted in the crucible or molten silicon can be directionally solidified in the crucible to provide for purification of the silicon. A lining can be deposited on an inner surface of the refractory material of the crucible in order to prevent or reduce contamination of the molten silicon contained within the crucible from the refractory material, such as contamination from boron, phosphorous, or aluminum. The lining can include a barrier lining comprising colloidal silica. The lining can include a barrier lining comprising silicon carbide particles bound together by a colloidal silica, or the lining can include an active purification lining comprising colloidal silica and, optionally, one or more flux materials. The lining can provide for a more pure final silicon for each directional solidification cycle, particularly with respect to boron, phosphorus, and aluminum contaminants.

The present disclosure describes a crucible for containing a molten silicon, the crucible comprising at least one refractory material having at least one inner surface defining an interior for receiving molten silicon, and a lining deposited onto the inner surface, the lining comprising colloidal silica.

The present disclosure also describes a method for the purification of silicon, the method comprising melting a first silicon in an interior of a melting crucible to provide a first molten silicon, the melting crucible comprising a first refractory material having at least one first inner surface defining the interior of the melting crucible, directionally solidifying the first molten silicon in a directional solidification mold to provide a second silicon, the directional solidification mold comprising a second refractory material having at least one second inner surface defining an interior of the directional solidification mold, and coating at least a portion of at least one of the first inner surface and the second inner surface with a lining comprising colloidal silica.

This summary is intended to provide an overview of subject matter of the present disclosure. It is not intended to provide an exclusive or exhaustive explanation of the invention. The detailed description is included to provide further information about the present disclosure.

### BRIEF DESCRIPTION OF THE DRAWINGS

In the drawings, like numerals can be used to describe similar elements throughout the several views. Like numerals having different letter suffixes can be used to represent different views of similar elements. The drawings illustrate generally, by way of example, but not by way of limitation, various examples discussed in the present document.

FIG. 1 is a cross-sectional view of an example of a crucible that can be used for the purification of silicon.

FIG. 2 is close-up cross-sectional view of an example of a lining coated on an inner surface of the example crucible of FIG. 1.

FIG. 3 is a cross-sectional view of an example of a crucible that can be used for the purification of silicon.

FIG. 4 is close-up cross-sectional view of an example of a lining coated on an inner surface of the example crucible of FIG. 3.

FIG. 5 is close-up cross-sectional view of another example of a lining coated on the inner surface of the example crucible of FIG. 3.

FIG. 6 is a cross-sectional view of an example of a crucible that can be used for the purification of silicon.

FIG. 7 is close-up cross-sectional view of an example of a lining coated on an inner surface of the example crucible of FIG. 6.

FIG. 8 is a cross-sectional view of an example heater that can be used for directional solidification of silicon.

FIG. 9 is a three-dimensional projection of an example apparatus for directional solidification of silicon, including an example heater positioned on top of an example directional solidification mold.

FIG. 10 is a flow diagram of an example method of purifying silicon.

FIG. 11 is a graph showing the change in purity with respect to boron in silicon purified in melting crucibles without an example lining compared to melting crucibles coated with the example lining.

### DETAILED DESCRIPTION

This disclosure describes an apparatus and method for purifying silicon using directional solidification. The apparatus and method can include the use of a lining within a vessel that holds molten silicon, wherein the lining can prevent or reduce contamination of the molten silicon from a refractory material of the vessel. The apparatus and method of the present invention can be used to make silicon crystals for use in solar cells.

### Definitions

The singular forms “a,” “an” and “the” can include plural referents unless the context clearly dictates otherwise.

As used herein, in some examples, terms such as “first,” “second,” “third,” and the like, as applied to other terms such as “mother liquor,”, “crystals,” “molten mixture,” “mixture,” “rinse solution,” “molten silicon,” and the like, are used simply as generic terms of differentiation between steps, and do not by themselves indicate priority of steps or order of steps, unless otherwise clearly indicated. For example, in some examples a “third mother liquor” may be an element, while no first or second mother liquor may be elements of the example. In other examples, a first, second, and third mother liquor may all be elements of an example.

As used herein, “conduit” can refer to a tube-shaped hole through a material, where the material is not necessarily tube-shaped. For example, a hole running through a block of material can be a conduit. The hole can be of greater length than diameter. A conduit can be formed by encasing a tube (including a pipe) in a material.

As used herein, “contacting” can refer to the act of touching, making contact, or of bringing substances into immediate proximity.

As used herein, “crucible” can refer to a container that can hold molten material, such as a container that can hold material as it is melted to become molten, a container that can receive the molten material and maintain the material in its molten state, and a container that can hold molten material as it solidifies or crystallizes, or a combination thereof.

As used herein, “directional solidification” or “directionally solidify” and the like can refer to crystallizing a material starting in approximately one location, proceeding in an approximately linear direction (e.g. vertically, horizontally, or perpendicular to a surface), and ending in approximately another location. As used in this definition, a location can be a point, a plane, or a curved plane, including a ring or bowl shape.

As used herein, “dross” can refer to a mass of solid impurities floating on a molten metal bath. It appears usually on the melting of low melting point metals or alloys such as tin, lead, zinc or aluminum, or by oxidation of the metal(s). It can be removed, e.g., by skimming it off the surface. With tin and lead, the dross can also be removed by adding sodium hydroxide pellets, which dissolve the oxides and form a slag. With other metals, salt fluxes can be added to separate the dross. Dross is distinguished from slag, which is a (viscous) liquid floating on the alloy, by being solid.

As used herein, “fan” can refer to any device or apparatus which can move air.

As used herein, “flux” can refer to a compound that is added to a molten metal bath to aid in the removal of impurities, such as within a dross. A flux material can be added to the molten metal bath so that the flux material can react with one or more materials or compounds in the molten metal bath to form a slag that can be removed.

As used herein, “furnace” can refer to a machine, device, apparatus, or other structure that has a compartment for heating a material.

As used herein, “heating element” can refer to a piece of material which generates heat. In some examples, a heating element can generate heat when electricity is allowed to flow through that material.

As used herein, “induction heater” can refer to a heater which adds heat to a material via the inducement of electrical currents in that material. The electrical currents can be generated by allowing an alternating current to travel through a coil of metal that is proximate to the material to be heated.

As used herein, “ingot” can refer to a mass of cast material. In some examples, the shape of the material allows the ingot to be relatively easily transported. For example, metal heated past its melting point and molded into a bar or block is referred to as an ingot.

As used herein, “lining” can refer to a layer of material applied to at least a portion of a surface of a crucible. The lining can act as a barrier between an inner surface of the crucible and a molten material contained within an interior of the crucible.

As used herein, “melt” or “melting” can refer to a substance changing from a solid to a liquid when exposed to sufficient heat. The term “melt” can also refer to a material that has undergone this phase transition to become a molten liquid.

As used herein, “molten” can refer to a substance that is melted, wherein melting is the process of heating a solid substance to a point (called the melting point) where it turns into a liquid.

As used herein, “monocrystalline silicon” can refer to silicon that has a single and continuous crystal lattice structure with almost no defects or impurities.

As used herein, “polycrystalline silicon” or “poly-Si” or “multicrystalline silicon” can refer to a material including multiple monocrystalline silicon crystals.

As used herein, “purifying” can refer to the physical or chemical separation of a chemical substance of interest from foreign or contaminating substances.

As used herein, “refractory material” can refer to a material which is chemically and physically stable at high temperatures, particularly at high temperatures associated with melting and directionally solidifying silicon. Examples of refractory materials include but are not limited to aluminum oxide, silicon oxide, magnesium oxide, calcium oxide, zirconium oxide, chromium oxide, silicon carbide, graphite, or a combination thereof.

As used herein, “side” or “sides” can refer to one or more sides, and unless otherwise indicated refers to the side or sides or an object as contrasted with one or more tops or bottoms of the object.

As used herein, “silicon” can refer to the element having the chemical symbol Si, and can refer to Si in any degree of purity, but generally refers to silicon that is at least 50% by weight pure, preferably 75% by weight pure, more preferably 85% pure, more preferably 90% by weight pure, and more preferably 95% by weight pure, and even more preferably 99% by weight pure.

As used herein, “separating” can refer to the process of removing a substance from another (e.g., removing a solid or a liquid from a mixture). The process can employ any suitable technique known to those of skill in the art, e.g., decanting the mixture, skimming one or more liquids from the mixture, centrifuging the mixture, filtering the solids from the mixture, or a combination thereof.

As used herein, “slag” can refer to by-product of smelting ore to purify metals. It can be considered to be a mixture of metal oxides; however, it can contain metal sulfides and metal atoms in the elemental form. Slags are generally used as a waste removal mechanism in metal smelting. In nature, the ores of metals such as iron, copper, lead, aluminum, and other metals are found in impure states, often oxidized and mixed in with silicates of other metals. During smelting, when the ore is exposed to high temperatures, these impurities are separated from the molten metal and can be removed. The collection of compounds that is removed is the slag. A slag can also be a blend of various oxides and other materials created by design, such as to enhance the purification of the metal.

As used herein, “tube” can refer to a hollow pipe-shaped material. A tube can have an internal shape that approximately matches its outer shape. The internal shape of a tube can be any suitable shape, including round, square, or a shape with any number of sides, including non-symmetrical shapes.

### Crucible for Directional Solidification

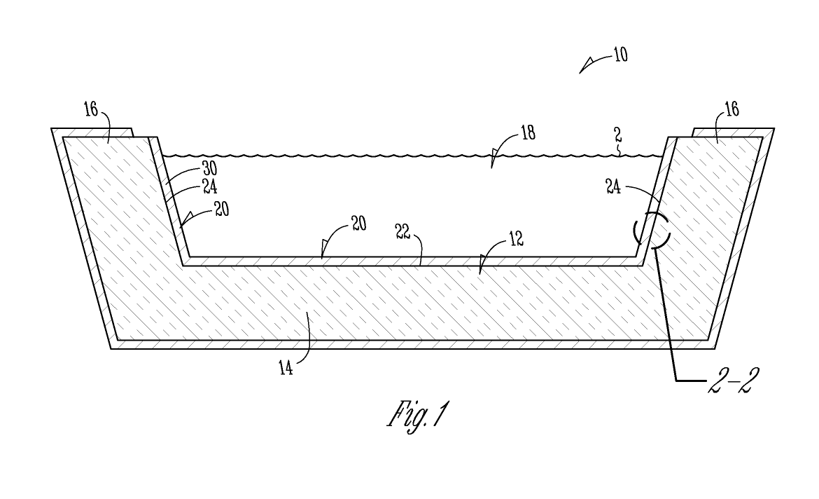

FIG. 1 shows an example of a crucible 10 according to the present disclosure. The crucible 10 can be used for directional solidification of silicon. For example, the crucible 10 can be used as a crucible for melting silicon within a furnace. The crucible 10 can also be used as the vessel in which directional solidification is carried out, also referred to as a directional solidification mold. The crucible 10 can be formed from at least one refractory material 12 that is configured to provide for melting of silicon or directional solidification of molten silicon, or both.

The crucible 10 can have a bottom 14 and one or more sides 16 extending upwardly from the bottom 14. The crucible 10 can be shaped similar to a thick-walled large bowl, which can have a circular or generally circular cross-section. The crucible 10 can have other cross-sectional shapes, including, but not limited to, a square shape, or a hexagon, octagon, pentagon, or any suitable shape, with any suitable number of edges.

The bottom 14 and sides 16 define an interior of the crucible 10 that can receive a molten material, such as molten silicon 2. The interior can also receive a solid material, such as solid silicon (not shown), that can be melted to form the molten material. The refractory material 12 can include an inner surface 20 that faces the interior 18. In an example, the inner surface 20 comprises an upper surface 22 of the bottom 14 and an inner surface 24 of the one or more sides 16.

The refractory material 12 can be any suitable refractory material, particularly a refractory material that is suitable for a crucible for melting or directional solidification of silicon. Examples of materials that can be used as the refractory material 12 include, but are not limited to aluminum oxide (Al₂O₃, also referred to as alumina), silicon oxide (SiO₂, also referred to as silica), magnesium oxide (MgO, also referred to as magnesia), calcium oxide (CaO), zirconium oxide (ZrO₂, also referred to as zirconia), chromium (III) oxide (Cr₂O₃, also referred to as chromia), silicon carbide (SiC), graphite, or a combination thereof. The crucible 10 can include one refractory material, or more than one refractory material. The refractory material or materials that are included in the crucible 10 can be mixed, or they can be located in separate parts of the crucible 10, or a combination thereof. The one or more refractory materials 12 can be arranged in layers. The crucible 10 can include more than one layer of one or more refractory materials 12. The crucible 10 can include one layer of one or more refractory materials 12. The sides 16 of the crucible 10 can be formed from a different refractory material than the bottom 14. The sides 16 as compared to the bottom 14 of the crucible 10 can be different thicknesses, include different compositions of material, include different amounts of material, or a combination thereof. In an example, the sides 16 can include a hot face refractory, such as aluminum oxide. The bottom 14 of the crucible 10 can include a heat-conductive material, such as, for example, silicon carbide, graphite, steel, stainless steel, cast iron, copper, or a combination thereof. In an example, the sides 16 include an aluminum oxide (alumina) refractory material, and the bottom 14 includes a silicon carbide refractory with a phosphorus binder.

Impurities can be passed from the refractory material 12 to the molten silicon 2 such that the impurity levels of some impurities can be higher than is acceptable for use of the silicon in photovoltaic devices. This can be particularly problematic during the directional solidification stages of purifying silicon, because directional solidification can be one of the final purification steps for the silicon such that the silicon in a crucible being used for directional solidification, such as crucible 10, is some of the purest silicon in the entire process. For example, boron or phosphorus impurities can be present in the refractory material 12. Even at very small boron or phosphorus levels, at the high temperatures experienced by the refractory material 12 due to the present of the molten silicon 2, the boron or phosphorus can be driven to diffuse out of the refractory material 12 and into the molten silicon 2. Also, if the refractory material 12 is made from or contains alumina (Al₂O₃), the alumina can undergo a reduction reaction in the presence of the molten silicon 2 to form metallic aluminum (Al) that can contaminate the molten silicon 2.

A lining 30 can be deposited onto the inner surface 20 of the refractory material 12, such as onto the upper surface 22 and the inner surface or surfaces 24. The lining 30 can be configured to prevent or reduce contamination of the molten silicon 2, such as via the transfer of impurities, such as boron (B), phosphorus (P), and aluminum (Al) from the refractory material 12 of the crucible 10 into the molten silicon 2, or via reaction an impurity or contaminant from the refractory material 12 into the molten silicon 2. The lining 30 can provide a barrier to the contaminants or impurities that can be present within the refractory material 12.

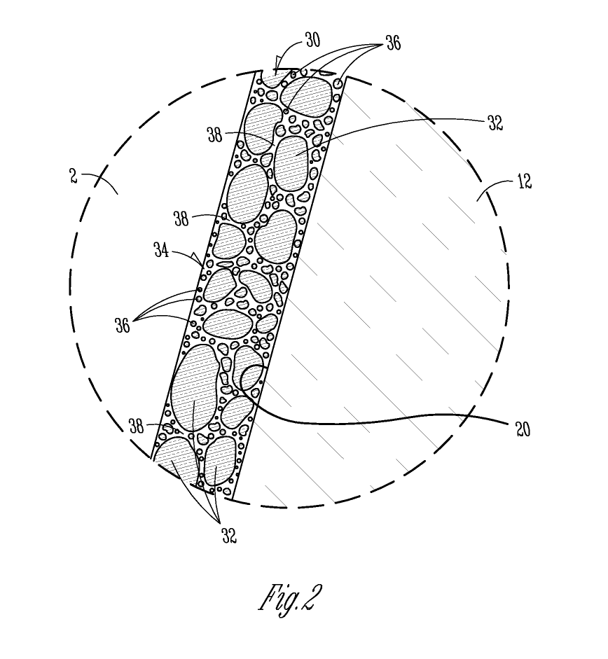

FIG. 2 shows a close-up cross-sectional view of the lining 30 deposited on the inner surface 20 of the refractory material 12. As shown in FIG. 2, the lining 30 can comprise a plurality of particles 32 bound together by a binder material 34. In an example, the particles 32 can comprise silicon carbide (SiC) and the binder material 34 can comprise a colloidal silica (SiO₂). The SiC particles 32 can each comprise one or more crystals of silicon carbide. The silicon carbide of the particles 32 can act as a barrier to contaminants or impurities, such as boron, phosphorus, and aluminum. The particles 32 can be nanoparticles, e.g., the particles 32 have a size or particle diameter of less than 5 millimeters, such as less than 3.5 millimeters.

The SiC particles 32 can be provided from a commercial supplier. In an example, the SiC particles 32 comprise a high-purity silicon carbide with low levels of contaminants or impurities that can lead to poor performance or that are undesirable in photovoltaic devices, such as boron, phosphorus, aluminum, and iron. In an example, the SiC particles 32 can be formed from a commercial silicon carbide having a boron level of less than 3 ppmw, such as less than 2.5 ppmw, for example less than 2.11 ppmw. The commercial silicon carbide can have a phosphorus level of less than 55 ppmw, such as less than 51.5 ppmw, for example less than 50 ppmw. The silicon carbide can have an aluminum level that is less than about 1700 ppmw, such as less than 1675 ppmw, for example less than about 1665 ppmw. The silicon carbide can have an iron level that is less than about 4100 ppmw. The silicon carbide can have a titanium content that is less than about 1145 ppmw. In an example, the SiC particles 32 are free or substantially free of boron and phosphorus. In an example, the SiC particles 32 can comprise other materials, so long as those materials do not cause an unacceptable level of undesirable impurities (such as boron, phosphorous, or aluminum) to leach into the molten silicon 2. In an example, the SiC particles 32 can include silica (SiO₂), elemental carbon (C), iron (III) oxide (Fe₂O₃), and magnesium oxide (MgO). In an example, the SiC particles 32 have the following composition (on a dry basis): 87.4 wt % SiC, 10.9 wt % SiO₂, 0.9 wet % carbon, 0.5 wt % Fe₂O₃, and 0.1 wt % MgO. In an example, the SiC particles 32 comprise silicon carbide sold under the trade name NANOTEK SiC, sold by Allied Mineral Products, Inc., Columbus, Ohio, USA. The NANOTEK SiC has a high purity with respect to boron, phosphorus, and aluminum, e.g., having about 2.11 ppmw boron, or less, and about 51.4 ppmw phosphorus, or less.

The binder 34 can be formed from a colloidal suspension of silica (SiO₂), referred to herein as colloidal silica. The colloidal silica can comprise a suspension of small, amorphous silica particles 36 suspended in a liquid phase 38. The SiC particles 32 can be mixed into the colloidal silica binder 34, and then the mixture can be deposited onto the inner surface 20 of the refractory material 12, such as by painting, spreading, or other common liquid deposition techniques. The colloidal silica binder 34 can act to bind and stabilize the SiC particles 32, even at the high temperatures associated with the presence of the molten silicon 2.

The colloidal silica of the binder 34 can be formed via the formation of silica nuclei, followed by growth of the silica particles 36 within the liquid phase 38. In an example, an alkali silicate solution, such as a sodium silicate solution, is partially neutralized, such as by selective removing at least a portion of the sodium from the sodium silicate. The neutralization of the alkali silicate can lead to the formation of silica nuclei and polymerization of the silica to form amorphous silica particles. The silica nuclei can have a size of between 1 nanometer (nm) and 5 nm, inclusive. The silica particles 36 can have a size, e.g. a diameter of between 1 nanometer (nm) and 100 nm, inclusive. In an example, the silica particles 36 have a size of between 10 nm and 30 nm, inclusive, such as about 20 nm. In an example, the colloidal silica that forms the binder 34 has a weight percentage of the silica particles 36 that is between 25 wt % and 60 wt % silica, inclusive, such as between 30 wt % and 50 wt % silica, inclusive, for example 40 wt % silica.

In an example, the colloidal silica used to make the binder 34 is a commercially-available colloidal silica, such as the colloidal silica sold under the trade name BINDZIL 2040 by WesBond Corp., Wilmington, Del., USA.

The SiC particles 32 and the binder 34 can be mixed together to form a precursor mixture that can be deposited onto the inner surface 20 to form the lining 30. The SiC particles 32 and the binder 34 can be mixed together in a weight ratio that can provide for coatability or spreadability of the precursor mixture, good slumping characteristics (e.g., a lack of slumping or minimal slumping after being spread), an acceptable drying time (e.g., long enough so that the mixture can be fully applied to the inner surface 20 before drying, but short enough to provide for a reasonable drying time within the manufacturing process), acceptable binding strength to the refractory material 12, and acceptable resistance to transmission of impurities or contaminants from the refractory material 12 to the molten silicon 2. In an example, the lining 30 comprises a weight composition of between 30 wt % SiC particles 32 and 80 wt % SiC particles, inclusive (e.g., between 20 wt % colloidal silica binder 34 and 70 wt % colloidal silica binder 34, inclusive), such as between 50 wt % SiC particles 32 and 70 wt % SiC particles 32, inclusive (e.g., between 30 wt % colloidal silica binder 34 and 50 wt % colloidal silica binder 34, inclusive), for example about 40 wt % SiC particles 32 and about 60 wt % colloidal silica binder 34. After drying (e.g., after removal of water and other liquids from the colloidal silica binder 34), the resulting lining 30 can be from 35 wt % SiC to 95% wt % SiC, inclusive (e.g., from 5 wt % silica to 65 wt % silica, inclusive), such as from 60 wt % SiC to 90 wt % SiC, inclusive (e.g., from 10 wt % silica to 40 wt % silica, inclusive), for example from 70 wt % SiC to 85 wt % SiC, inclusive (e.g., from 15 wt % silica to 30 wt % silica, inclusive), such as about 80 wt % SiC and about 20 wt % silica.

The lining 30 can be relatively free of contaminants, such as boron, phosphorus, and aluminum. In an example, the boron content in the lining 30 is less than about 5 ppmw, such as less than about 3 ppmw, for example, less than about 2 ppmw. The phosphorus content in the lining 30 can be less than about 70 ppmw, such as less than about 60 ppmw, for example less than about 50 ppmw. In an example, the phosphorus level in the lining 30 can be as low as 11.25 ppmw. In an example, the aluminum content in the lining 30 can be less than about 0.75 wt %, such as less than about 0.6 wt %, for example less than about 0.5 wt %.

The thickness of the lining 30 can depend on the conditions within and around the crucible 10 and on the stage of processing that is being performed within the crucible 10. For example, if the crucible 10 is being used as a melting crucible in order to melt a solid silicon to form the molten silicon 2, than a relatively thick lining 30 can be required due to the high temperature throughout the crucible 10 because the crucible 10 is placed within a furnace. Similarly, if the crucible 10 is being used as a mold for directional solidification, then a relatively thin lining 30 can be required due to a less volatile environment within the molten silicon 2 and a relatively lower temperature. In an example, the lining 30 has a thickness from about 1 millimeter (mm) to about 25 mm, inclusive, such as from about 2 mm to about 15 mm, inclusive, for example, from about 3 mm to about 10 mm, for example from about 4 mm to about 5 mm, inclusive, such as about 4, about 4.1 mm, about 4.2 mm, about 4.3 mm, about 4.4 mm, about 4.5 mm, about 4.6 mm, about 4.7 mm, about 4.8 mm, about 4.9 mm, about 5 mm, about 5.1 mm, about 5.2 mm, about 5.3 mm, about 5.4 mm, about 5.5 mm, about 5.6 mm, about 5.7 mm, about 5.8 mm, about 5.9 mm, and about 6 mm.

In an example, the mixture of the SiC particles 32 and the colloidal silica binder 34 can be a liquid or liquid suspension that can be coated onto the inner surface 20 by known liquid coating methods. In an example, the mixture can be coated onto the inner surface 20 via at least one of painting, spraying, spreading, blade coating, drop coating or dip coating. The mixture of the SiC particles 32 and the colloidal silica binder 34 can be applied onto the inner surface 20 to have a uniform or substantially uniform thickness. The coated mixture can then be allowed to dry, which can allow the silica particles 36 to grow as the liquid phase 38 dries away such that the SiC particles 32 become bound by a substantially solid silica binder 34 to form the lining 30.

In an example, the mixture of the SiC particles 32 and the colloidal silica binder 34 can be applied as a plurality of coats onto the inner surface 20 of the refractory material 12. Each coat of the mixture can be applied, such as via painting, spraying, spraying, or any other coating method, and allowed to dry for a specified period of time before applying a subsequent coat. In an example, from 2 to 10 coats or more can be applied to the inner surface 20, such as 2 coats, 3 coats, 4 coats, 5 coats, 6 coats, 7 coats, 8 coats, 9 coats, or 10 coats. In an example, between coats the lining can be allowed to dry from about 15 minutes to about 6 hours, inclusive, such as from about 30 minutes to about 2 hours, inclusive. After all the coats have been applied, the lining 30 can be allowed to dry for from about 1 hour to about 10 hours, inclusive, such as from about 2 hours to about 8 hours, inclusive, such as from about 4 hours to about 6 hours, inclusive, such as about 4 hours, about 4.5 hours, about 5 hours, about 5.5 hours, and about 6 hours.

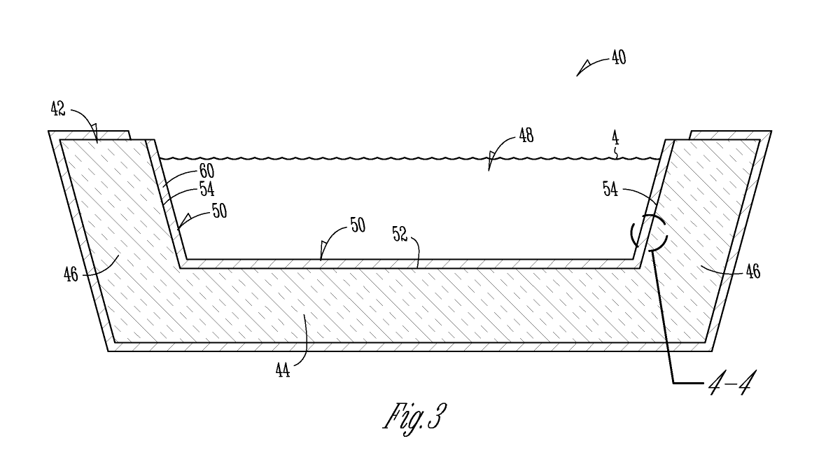

FIG. 3 shows another example of a crucible 40 according to the present disclosure. Like the crucible 10 discussed above with respect to FIGS. 1 and 2, the crucible 40 can be used for directional solidification of silicon. For example, the crucible 40 can be used as a crucible for melting silicon within a furnace or as a directional solidification mold. The crucible 40 can be formed from at least one refractory material 42 that is configured to provide for melting of silicon or directional solidification of molten silicon, or both. The refractory material 42 can be one or more of the refractory materials described above with respect to the refractory material 12 of crucible 10.

The crucible 40 can have a bottom 44 and one or more sides 46 extending upwardly from the bottom 44. The crucible 40 can be shaped similar to a thick-walled large bowl, which can have a circular or generally circular cross-section. The crucible 40 can have other cross-sectional shapes, including, but not limited to, a square shape, or a hexagon, octagon, pentagon, or any suitable shape, with any suitable number of edges.

The bottom 44 and sides 46 can define an interior 48 of the crucible 40 that can receive a molten material, such as a molten silicon 4. The interior 48 can also receive a solid material, such as solid silicon (not shown), that can be melted to form the molten material. The refractory material 42 can include an inner surface 50 that faces the interior 48. In an example, the inner surface 50 comprises an upper surface 52 of the bottom 44 and an inner surface 54 of the one or more sides 46.

A lining 60 can be deposited onto the inner surface 50 of the crucible 40, such as onto the upper surface 52 and the inner surface or surfaces 54. Like the lining 30 described above with respect to FIGS. 1 and 2, the lining 60 can be configured to prevent or reduce contamination of the molten silicon 4, such as by providing a barrier to contaminants or impurities that can be present within the refractory material 42. The lining 60 can also be configured to provide for active purification of the molten silicon 4. As used herein, “active purification” of molten silicon can refer to one or more chemical reactions between one or more components of the lining 60 and one or more components of the molten silicon 4 that can form a dross or a slag within the molten silicon 4 that can be removed.

The lining 60 can provide for active purification of the molten silicon 4 by comprising at least one material that can act as a flux for the formation of slag or dross within the molten silicon 4. In an example, the lining 60 can comprise silica (SiO₂). Silica is often added to molten silicon as a flux, such as loose particles of silica, to remove aluminum or other unwanted impurities from the molten silicon. Providing a lining 60 that comprises primarily silica can substantially increase the surface area of molten silicon 4 that is exposed to silica. The high temperature of the molten silicon 4 can modify the silica within the lining 60 so that the lining 60 can chemically interact with the molten silicon 4 in substantially the same way that a flux within the molten silicon 4 will. This can allow for mass transfer of contaminants or impurities from the molten silicon 4 into the lining 60, such as via absorption, or reaction with components of the lining 60, or both, to remove the contaminants or impurities from the molten silicon 4.

In an example, the lining 60 can be formed from a colloidal suspension of silica, described herein as a colloidal silica, similar to the colloidal silica that forms the binder 34 of the lining 30, described above. However, the lining 60 does not include the SiC particles 32. When the SiC particles are not present, the silica of the lining 60 is free to react with components of the molten silicon 4 to form a slag. Thus, the lining 60 can act as a flux coating that provides for further active purification of the molten silicon 4.

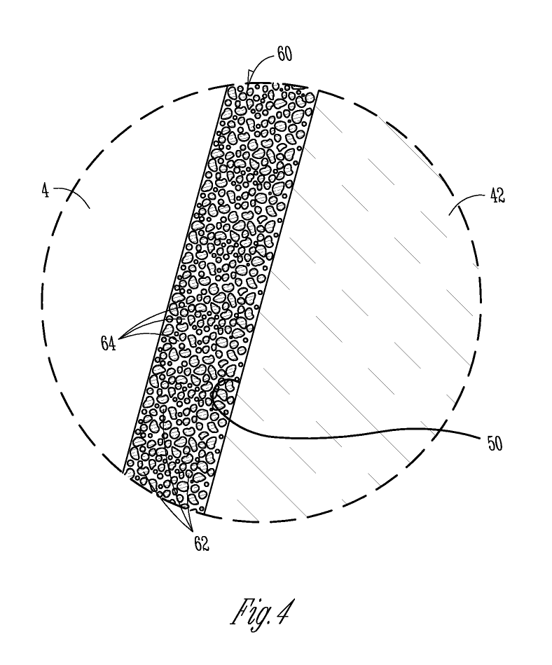

FIG. 4 shows a close-up cross-sectional view of the lining 60 deposited on the inner surface 50 of the refractory material 52. The colloidal silica that can form lining 60 can comprise a suspension of small, amorphous silica particles 62 suspended in a liquid phase 64. The colloidal silica can be formed via the formation of silica nuclei, followed by growth of the silica particles 62 within the liquid phase 64. In an example, an alkali silicate solution, such as a sodium silicate solution, is partially neutralized, such as by selective removing at least a portion of the sodium from the sodium silicate. The neutralization of the alkali silicate can lead to the formation of silica nuclei and polymerization of the silica to form amorphous silica particles. The silica nuclei can have a size of between 1 nanometer (nm) and 5 nm, inclusive. The silica particles 62 can have a size, e.g. a diameter of between 1 nanometer (nm) and 100 nm, inclusive. In an example, the silica particles 62 have a size of between 10 nm and 30 nm, inclusive, such as about 20 nm. In an example, the colloidal silica that forms the lining 60 has a weight percentage of the silica particles 62 that is between 25 wt % and 60 wt % silica, inclusive, such as between 30 wt % and 50 wt % silica, inclusive, for example 40 wt % silica.

In an example, the colloidal silica used to form the lining 60 is a commercially-available colloidal silica, such as the colloidal silica sold under the trade name BINDZIL 2040 by WesBond Corp., Wilmington, Del., USA.

In an example, the lining 60 consists essentially of silica, e.g., that is formed from the colloidal silica, described above, such that materials that would substantially alter the ability of the lining 60 to actively purify the molten silicon 4 are not present in the lining 60. In an example, the lining 60 consists of silica, e.g., formed from the colloidal silica described above.

The thickness of the lining 60 can depend on the conditions within and around the crucible 40 and on the stage of processing that is being performed within the crucible 40. For example, if the crucible 40 is being used as a melting crucible in order to melt a solid silicon to form the molten silicon 4, than a relatively thick lining 60 can be required due to the high temperature throughout the crucible 40 because the crucible 40 is placed within a furnace. Similarly, if the crucible 40 is being used as a mold for directional solidification, then a relatively thin lining 60 can be required due to a less volatile environment within the molten silicon 2 and a relatively lower temperature. In an example, the lining 60 has a thickness from about 1 millimeter (mm) to about 25 mm, inclusive, such as from about 2 mm to about 15 mm, inclusive, for example, from about 3 mm to about 10 mm, for example from about 4 mm to about 5 mm, inclusive, such as about 4, about 4.1 mm, about 4.2 mm, about 4.3 mm, about 4.4 mm, about 4.5 mm, about 4.6 mm, about 4.7 mm, about 4.8 mm, about 4.9 mm, about 5 mm, about 5.1 mm, about 5.2 mm, about 5.3 mm, about 5.4 mm, about 5.5 mm, about 5.6 mm, about 5.7 mm, about 5.8 mm, about 5.9 mm, and about 6 mm.

In an example, the colloidal silica can be a liquid or liquid suspension that can be coated onto the inner surface 50 by known liquid coating methods to form the lining 60. In an example, the colloidal silica can be coated onto the inner surface 50 via at least one of painting, spreading, blade coating, drop coating or dip coating. The colloidal silica can be applied onto the inner surface 50 to have a uniform or substantially uniform thickness. The coated colloidal silica can then be allowed to dry, which can allow the silica particles 62 to grow as the liquid phase 64 dries away such that the SiC particles 62 form a substantially solid silica lining 60. Like the lining 30, described above, the lining 60 can be applied as a plurality of coats, where each coat can be allowed to dry for a first drying time between coats, and for a final drying time, such as from about 2 hours to about 10 hours, inclusive, for example about 6 hours, after applying the last coat.

In an example, the lining 60 can comprise other materials that can provide for further active purification of the molten silicon 4. For example, the lining 60 can comprise other flux materials that can provide for the formation of slag from components within the molten silicon 4. Examples of flux materials that can be included in the lining 60 include, but are not limited to, sodium carbonate (Na₂CO₃), calcium oxide (CaO), and calcium fluoride (CaF₂). In an example, the lining 60 can have a composition of between about 30 wt % SiO₂ and about 55 wt % SiO₂, inclusive, between about 40 wt % Na₂CO₃ and about 65 wt. % Na₂CO₃, inclusive, between about 0 wt. % and about 15 wt. % CaO, inclusive, and between about 0 wt % CaF₂ and about 25 wt % CaF₂, inclusive. In an example, the composition of the lining 60 can comprise about 42.7 wt % SiO₂, about 50.6 wt. % Na₂CO₃, about 1.7 wt. % CaO, and about 5 wt % CaF₂. Further description of flux compositions can be found in the U.S. Provisional Application to Turenne et al., entitled, “FLUX COMPOSITION USEFUL IN DIRECTIONAL SOLIDICIATION FOR PURIYING SILICON,” Attorney Docket No. 2552.036PRV, filed on the same date as this application, which is herein incorporated by reference in its entirety.

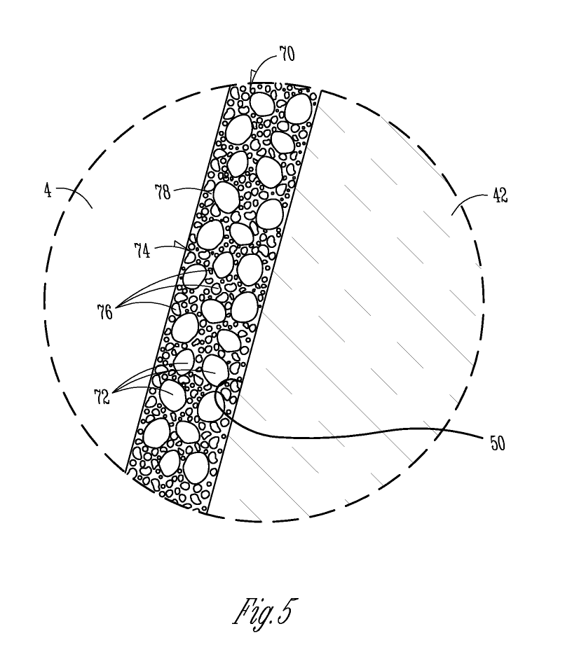

In an example, shown in FIG. 5, a lining 70 can include additional flux material added to a lining 70 in the form of flux particles 72 that are bound together with a colloidal silica binder 74, similar to how the SiC particles 32 are bound together with the colloidal silica binder 34 to form the lining 30, described above. Like the colloidal silica binder 34 and the colloidal silica of lining 60, described above, the colloidal silica binder 74 can comprise a suspension of small, amorphous silica particles 76 suspended in a liquid phase 78. The silica particles 76 can have a size, e.g. a diameter of between 1 nanometer (nm) and 100 nm, inclusive. In an example, the silica particles 76 have a size of between 10 nm and 30 nm, inclusive, such as about 20 nm. In an example, the colloidal silica that forms the binder 74 has a weight percentage of the silica particles 76 that is between 25 wt % and 60 wt % silica, inclusive, such as between 30 wt % and 50 wt % silica, inclusive, for example 40 wt % silica.

The flux particles 72 and the binder 74 can be mixed together to form a precursor mixture that can be deposited onto the inner surface 50 to form the lining 70. The flux particles 72 and the binder 74 can be mixed together in a weight ratio that can provide for good coatability or spreadability of the precursor mixture while also providing for good binding strength to the refractory material 52. The weight ratio of the flux particles 72 and the binder 74 can also be selected so that the silica of the colloidal silica binder 74 and the flux particles 72 will be available for reaction with one or more components of the molten silicon 4 so that a slag can be formed. As such, the weight ratio of flux particles 72 to binder 74 may be substantially lower than the weight ratio of SiC particles 32 to binder 34 described above with respect to lining 30 (FIGS. 1 and 2), so that a larger surface area of the colloidal silica binder 74 will be exposed to the molten silicon 4. In an example, the lining 70 comprises a weight composition of between 5 wt % flux particles 72 and 50 wt % flux particles 72, inclusive (e.g., between 50 wt % colloidal silica binder 74 and 95 wt % colloidal silica binder 74, inclusive), such as between 10 wt % flux particles 72 and 35 wt % flux particles 72, inclusive (e.g., between 65 wt % colloidal silica binder 74 and 90 wt % colloidal silica binder 74, inclusive), for example between 15 wt % flux particles 72 and 25 wt % flux particles 72, inclusive (e.g., between 75 wt % colloidal silica binder 72 and 85 wt % colloidal silica binder 74, inclusive), such as about 20 wt % flux particles 72 and about 80 wt % colloidal silica binder 74.

In an example, the lining 70 consists essentially of silica, e.g., that is formed from the colloidal silica binder 74, and of at least one flux material, such as at least one of sodium carbonate (Na₂CO₃), calcium oxide (CaO), and calcium fluoride (CaF₂), such that materials that would substantially alter the ability of the lining 70 to actively purify the molten silicon 4 are not present in the lining 70. In an example, the lining 70 consists of silica, e.g., formed from the colloidal silica binder 74, and of at least one flux material, such as at least one of sodium carbonate (Na₂CO₃), calcium oxide (CaO), and calcium fluoride (CaF₂).

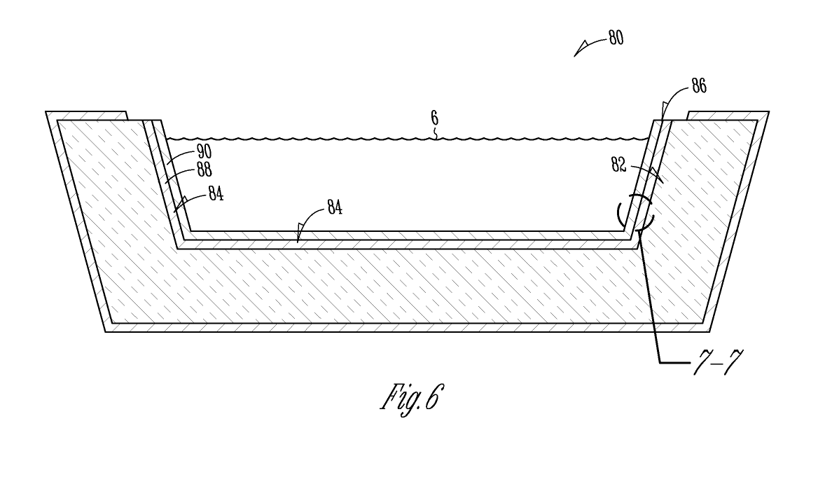

FIG. 6 shows another example of a crucible 80 according to the present disclosure. The crucible 80 can include a refractory material 82 having an inner surface 84, wherein a lining 86 can be deposited on the refractory material 82. The lining 86 can comprise a first layer 88 that is in contact with the inner surface 84 of the refractory material 82 and a second layer 90 that is in contact with a molten silicon 6 if the molten silicon is present in the crucible 80. The refractory material 82 can be one or more of the refractory materials described above with respect to the refractory material 12 of crucible 10.

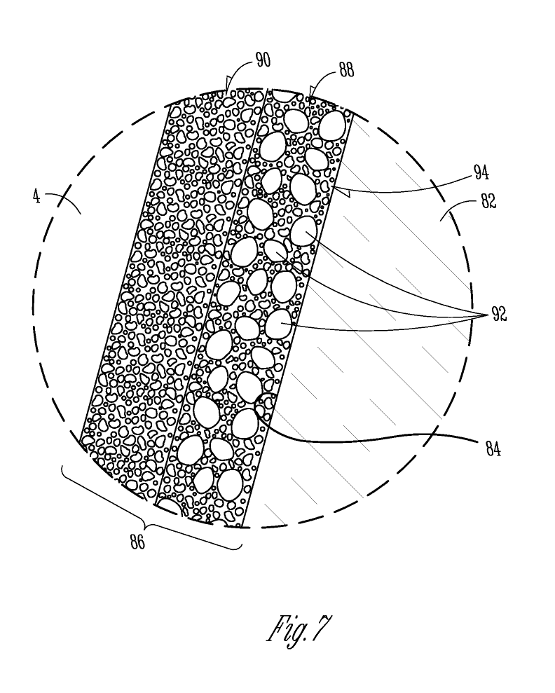

FIG. 7 shows a close-up cross-sectional view of the lining 86 deposited on the inner surface 84 of the refractory material 82. In an example, the first layer 88 can comprise a plurality of particles 92 bound together by a binder material 94. The first layer 88 can be substantially the same as the lining 30 described above with respect to FIGS. 1 and 2. For example, the particles 92 can comprise silicon carbide (SiC) and the binder 94 can comprise a colloidal silica (SiO₂). The second layer 90 can comprise an active purification layer that is substantially the same as the lining 60 described above with respect to FIGS. 3 and 4 (e.g., a colloidal silica lining) or as the lining 70 described above with respect to FIGS. 5 and 6 (e.g., a lining of flux material particles bound together by a colloidal silica binder). The first layer 88 can provide a passive barrier layer that prevents or reduces the passage of contaminants or impurities from the refractory material 82 to the molten silicon 6 and the second layer 90 can provide for active purification of the molten silicon 6 as a flux-containing layer.

In an example, the crucible, such as crucible 10, 40, or 80 described above, can hold about 1 metric tonne of molten silicon, or more. In an example, the crucible can hold about 1.4 metric tonnes of molten silicon, or more. In an example, the crucible can hold about 2.1 metric tonnes of molten silicon, or more. In an example, the crucible can hold at least about 1, 1.2, 1.4, 1.6, 1.8, 2.0, 2.1, 2.5, 3, 3.5, 4, 4.5, or 5 metric tonnes of silicon molten, or more.

A crucible, such as the crucibles 10, 40, 80 described above, can include other features, for example that can provide for more efficient melting or directional solidification of silicon within the crucible. Examples of structures or features that can be included in the crucible include, but are not limited to, one or more insulating layers or other structures, one or more heat conducting layers or other structures, one or more jackets, and one or more anchors for holding layers together or to prevent or reduce loosening. Examples of structures that can be included in the crucible are described in the U.S. patent application Ser. No. 12/947,936 to Nichol et al., entitled “APPARATUS AND METHOD FOR DIRECTIONAL SOLIDIFICATION OF SILICON,” filed on Nov. 17, 2010, assigned to the assignee of this application, which is herein incorporated by reference in its entirety.

### Top Heater

If a crucible according to this disclosure, such as the crucibles 10, 40, 80 described above, are used for directional solidification, a top heater can also be included and positioned on top of the crucible to apply heat to the crucible and the molten silicon within the crucible. The top heater can have a cross-sectional shape that approximately matches the cross-sectional shape of the crucible. Application of heat to the crucible by the top heater can allow for control of the temperature of the molten silicon in the crucible. The top heater can also be positioned on top of the crucible without heating, so that the top heater can serve as an insulator to control the release of heat from the crucible. By controlling the temperature or release of heat of the crucible, a desired temperature gradient can be provided, which can allow for more highly controlled directional solidification. Ultimately, control over the temperature gradient can allow a more effective directional solidification in which the resulting purity of the silicon is maximized.

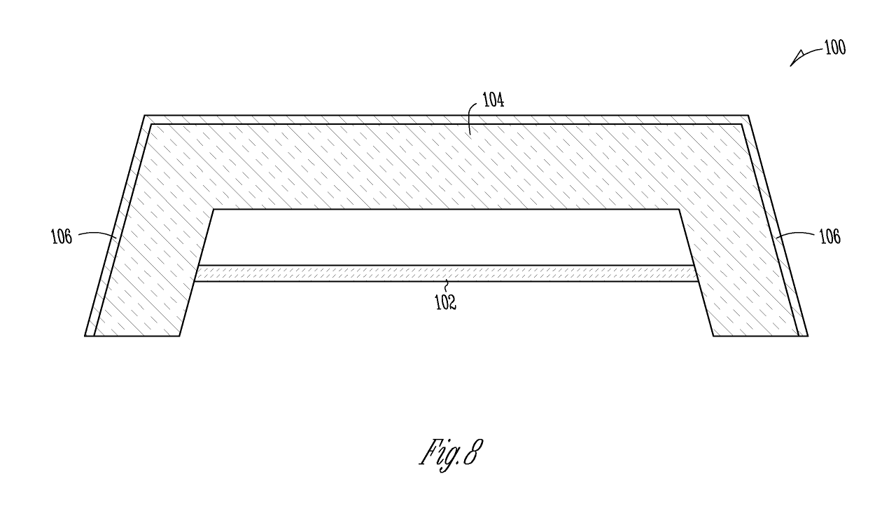

FIG. 8 shows an example of a top heater 100. The top heater 100 can include one or more heating members 102. Each of the one or more heating members 102 can independently include any suitable material. For example, each of the one or more heating members 102 can independently include a heating element, where the heating element can include silicon carbide, molybdenum disilicide, graphite, or a combination thereof; and, each of the one or more heating members 102 can alternatively independently include an induction heater. In an example, the one or more heating members are positioned at approximately the same height. In another example, the one or more heating members are positioned at different heights.

In an example, the heating members 102 can include silicon carbide, which can have certain advantages. For example, silicon carbide heating members 102 can be less likely to corrode at high temperatures in the presence of oxygen. Oxygen corrosion can be reduced for heating elements including corrodible materials by using a vacuum chamber, but silicon carbide heating members 102 can avoid corrosion without a vacuum chamber. Additionally, silicon carbide heating members 102 can be used without water-cooled leads. In an example, the heating elements are used in a vacuum chamber, with water-cooled leads, or both. In an example, the heating members 102 are used without a vacuum chamber, without water-cooled leads, or without both.

In an example, the one or more heating members 102 are induction heaters. The induction heaters 102 can be cast into one or more refractory materials.

The refractory material containing the induction heating coil or coils can then be positioned over the bottom mold. The refractory material can be any suitable material, including, but not limited to aluminum oxide, silicon oxide, magnesium oxide, calcium oxide, zirconium oxide, chromium oxide, silicon carbide, graphite, or a combination thereof. In another example, the induction heaters 102 are not cast into one or more refractory materials.

The one or more heating members 102 can have an electrical system such that if at least one heating member 102 fails, any remaining functional heating members 102 can continue to receive electricity and to produce heat. In an example, each heating member 102 has its own circuit.

The top heater 100 can include insulation 104. The insulation 104 can include any suitable insulating material, including, but not limited to, insulating brick, a refractory, a mixture of refractories, insulating board, ceramic paper, high temperature wool, or a mixture thereof. Insulating board can include high temperature ceramic board. A bottom edge of the insulating material 104 and the one or more heating members 102 can be at approximately the same height, or the heating members 102 can be positioned above the height of the bottom edge of the insulating material 104, or the bottom edge of the insulating material 104 can be positioned above the height of the heating members 102. Other configurations of the one or more heating members 102 and the insulating material 104 can be used, such as the one or more heating members 102 being an induction heater, the insulating material 104 including a refractory material, wherein the one or more heating members 102 are encased in the refractory material 104. In such an example, additional insulating material can also be optionally included, where the additional insulating material can be refractory material, or the additional insulating material can be another suitable insulating material.

The top heater 100 can include an outer jacket 106. The outer jacket 106 can include any suitable material, including, but not limited to steel, stainless steel, copper, cast iron, a refractory material, a mixture of refractory materials, or a combination thereof. The insulating material 104 can be disposed at least partially between the one or more heating members 102 and the outer jacket 106. The bottom edge of the outer jacket 106 can be approximately even with the bottom edge of the insulating material 104 and with the one or more heating members 102, or the bottom edge of the outer jacket 106 can be offset from the bottom edge of the insulating material 104 or with the one or more heating members 102, or both. In an example, a portion of the outer jacket 106 that covers an edge of the insulating material 104 can include a material with a relatively low conductivity, such as a suitable refractory, such as aluminum oxide, silicon oxide, magnesium oxide, calcium oxide, zirconium oxide, chromium oxide, silicon carbide, graphite, or a combination thereof.

The top heater outer jacket 106 can include structural members, such as members that can add strength or rigidity to the top heater 100. The structural members can include steel, stainless steel, copper, cast iron, a refractory material, a mixture of refractory materials, or a combination thereof. In an example, the top heater outer jacket 106 can include one or more structural members that extend from outside of the top heater outer jacket 106 in a direction that is away from a center of the top heater 100, and that extend horizontally around the circumference or perimeter of the top heater 100. The one or more horizontal structural members can be located, for example, at a lower edge of the outside of the top heater outer jacket 106, at the top edge of the outside of the top heater outer jacket 106, or at any position in between the bottom and top edges of the outside of the top heater outer jacket 106. In an example, the top heater 100 includes three horizontal structural members, with one located at the bottom edge of the top heater outer jacket 106, one located at the upper edge of the top heater outer jacket 106, and one located in-between the lower and upper edges of the top heater outer jacket 106.

The top heater outer jacket 106 can include one or more structural members on the outside of the top heater outer jacket 106 that extend for outside of the top heater outer jacket 106 in a direction that is away from the center of the top heater 100 vertically from the bottom of the outside of the top heater outer jacket 106 to the top of the outside of the top heater outer jacket 106. In an example, the top heater outer jacket 106 can include eight vertical structural members. The vertical structural members can be evenly spaced around the circumference or perimeter of the top heater 100. In an example, the top heater outer jacket 106 can include both vertical and horizontal structural members. The top heater outer jacket 106 can include structural members that extend across the top of the top heater outer jacket 106. The structural member on the top can extend from one outer edge of the top of the top heater outer jacket 106 to another edge of the top of the top heater outer jacket 106. The structural members on the top can also extend partially across the top of the outer jacket 106. The structural members can be strips, bars, tubes, or any suitable structure for adding structural support to the top heater. The structural members can be attached to the top heater outer jacket 106 via welding, brazing, or other suitable method. The structural members can be adapted to facilitate transportation and physical manipulation of the apparatus. For example, the structural members on the top of the outside of the top heater outer jacket 106 can be tubes of sufficient size, strength, orientation, spacing, or a combination thereof, such that a particular fork-lift or other lifting machine could lift or move or otherwise physically manipulate the top heater. In another example, the structural members described above as being located on the outside of the top heater outer jacket 106 can alternatively or additionally be located on the inside of the top heater outer jacket 106. In another example, the top heater 100 can be moved using a crane or other lifting device, using chains attached to the top heater 100, including chains attached to structural members of the top heater or to non-structural members of the top heater 100. For example, chains can be attached to the upper edge of the top heater outer jacket 106 to form a bridle for a crane to lift and otherwise move the top heater 100.

### Cooling

As discussed above, by controlling the temperature gradient in the crucible, a highly controlled directional solidification can be accomplished. High degrees of control over the temperature gradient and the corresponding directional crystallization can allow a more effective directional solidification, providing a silicon of high purity. In an example, the directional solidification can proceed from approximately the bottom of the crucible to the top, such that the temperature gradient has a lower temperature at the bottom and a higher temperature at the top. In an example with a top heater 100, the top heater 100 can be one way to control the entry or loss of heat from the crucible. A conducting refractory material can also be used in the crucible to induce heat loss from the bottom of the crucible. The crucible can also include insulating material on the sides of the crucible to prevent heat loss therefrom, to encourage the formation of a vertical thermal gradient, and to discourage the formation of a horizontal thermal gradient. In an example, one or more fans can be used to blow cooling air across the bottom of the crucible, for example across the bottom of an outer jacket of the crucible, to control heat loss from the bottom of the crucible. In an example, circulation of ambient air without the use of a fan can be used to cool the crucible, including the bottom of the crucible.

In an example, one or more heat transfer fins can be attached to the bottom of the crucible outer jacket to facilitate air cooling. One or more fans can enhance the cooling effect of cooling fins by blowing air across the bottom of the outer jacket. Any suitable number of fins can be used. The one or more fins can absorb heat from the bottom of the apparatus and allow the heat to be removed by air cooling, facilitated by the surface area of the fin. For example, the fins can be made of copper, cast iron, steel, or stainless steel.

In an example, at least one liquid conduit can be included, wherein the at least one liquid conduit is configured to allow a cooling liquid to pass through the conduit, thereby transferring heat away from the crucible. The cooling liquid can be any suitable cooling liquid. The cooling liquid can be one liquid or a mixture of more than one liquid. Examples of cooling liquids that can be used include, but are not limited to, at least one of water, ethylene glycol, diethylene glycol, propylene glycol, an oil, and a mixture of oils.

In an example, the at least one liquid conduit can include a tube. The tube can include any suitable material for heat transfer, such as copper, cast iron, steel, stainless steel, a refractory material, a mixture of refractory materials, or a combination thereof. The at least one liquid conduit can include a conduit through a material. The conduit can be through any suitable material, such as through a material that includes copper, silicon carbide, graphite, cast iron, steel, stainless steel, a refractory material, a mixture of refractory materials, or a combination thereof. The at least one liquid conduit can be a combination of a tube and a conduit through a material. In an example, the at least one liquid conduit can be located adjacent to the bottom of the apparatus, within the bottom of the apparatus, or a combination of being adjacent to the bottom of the apparatus and being within the bottom of the apparatus.

The liquid conduit can encompass a variety of configurations that allow a cooling liquid to transfer heat away from the directional solidification mold. A pump can be used to move the cooling liquid. A cooling system can be used to remove heat from the cooling liquid. For example, one or more tubes, including pipes, can be used. The one or more tubes can be any suitable shape, including round, square, or flat. The one or more tubes can be coiled. The one or more tubes can be adjacent to the outside of the outer jacket. In an example, the one or more tubes can be adjacent to the bottom of the outside of the outer jacket. The one or more tubes can contact the outer jacket such that sufficient surface area contact can occur to allow efficient transfer of heat from the apparatus to the cooling liquid. The one or more tubes can contact the outer jacket in any suitable fashion, including along an edge of a tube. The one or more tubes can be welded, brazed, soldered, or attached by any suitable method to the outside of the outer jacket. The one or more tubes can be flattened to the outside of the outer jacket to enhance the efficiency of heat transfer.

In an example, the at least one liquid conduit can be one or more conduits running through the bottom of the crucible. A conduit running through the bottom of the crucible can be a tube encased in a refractory that is included in the crucible. A tube can enter one part of the outer jacket, run through a refractory material or conductive material or a combination thereof at the bottom of the crucible, and exit another part of the outer jacket. A tube encased in the bottom refractory or bottom conductive material of the crucible can be coiled, or arranged in any suitable shape, including moving back and forth one or more times before exiting the bottom of the crucible.

In an example, the at least one liquid conduit includes a tube encased in a refractory material, a heat-conductive material, or a combination thereof, wherein the material is a block of material large enough for the crucible to be placed on. The conduit can be through any suitable material. For example, the conduit can be through a material that includes copper, silicon carbide, graphite, cast iron, steel, stainless steel, a refractory material, a mixture of refractory materials, or a combination thereof. The cooling liquid can remove heat from the refractory material on which the crucible sits, thereby removing heat from the bottom of the crucible.

### General

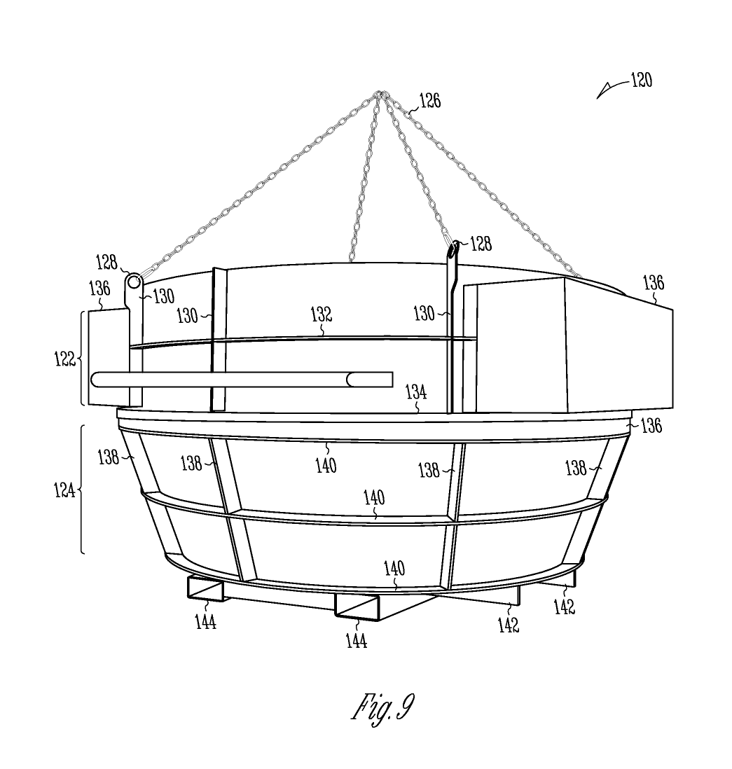

FIG. 9 illustrates an example of an apparatus 120 for directional solidification of silicon, including a top heater 122 positioned on top of a crucible 124. Chains 126 can be connected to the top heater 122 via holes 128 in vertical structural members 130. The chains 126 can form a bridle, which can allow the top heater 122 to be moved by the use of a crane. The apparatus can also be moved, for example, by placing the crucible 124 on a scissor lift while leaving the top heater 122 over the crucible 124.

The vertical structural members 130 can extend vertically from the bottom edge of an outer jacket of the top heater 122 to a top edge of the outer jacket of the top heater 122. The vertical structural members 130 can be located on the outside of the top heater outer jacket and extend from the jacket parallel to a direction that is away from the center of the top heater 122. The top heater 122 can also include one or more horizontal structural members 132, which can be located on the outside of the top heater outer jacket and can extend from the jacket in a direction that is parallel to a direction that is away from the center of the top heater 122. The top heater 122 can also include a lip 134 that can be part of the outer jacket of the top heater 122. The lip 134 can protrude away from the outer jacket of the top heater 122. The lip 134 can extend inward toward the center axis of the top heater 122 such that it covers insulation of the top heater 122 to any suitable extent. Alternatively, the lip 134 can extend inward only enough to cover the bottom edge of the outer jacket of the top heater 122. One or more screen boxes 136 can enclose ends of heating members that protrude from the outer jacket of the top heater 122, protecting users from the heat and electricity that can be present in and near the ends of these members.

Insulation 138 can be located between the top heater 122 and the crucible 124. At least part of the one or more insulating layers of the crucible 124 can extend above the height of the outer jacket of the crucible 124. The crucible 124 can include one or more vertical structural members 140. The vertical structural members 140 can be located on an outer surface of the outer jacket of the crucible 124, extending away from the outer jacket parallel to a direction that is away from the center of the crucible 124. The vertical structural members 140 can extend vertically from the bottom edge of the outer jacket to the top edge of the outer jacket. The crucible 124 can also include one or more horizontal structural members 142. The horizontal structural members 142 can be located on the outer surface of the outer jacket of the crucible 124, extending away from the outer jacket parallel to a direction that is away from the center of the crucible 124. The horizontal structural members 142 can extend horizontally around the circumference of the crucible 124. The crucible 124 can also include bottom structural members 144 and 146. The bottom structural members 144 and 146 can extend away from the outer jacket parallel to a direction that is away from the center of the crucible 124. The bottom structural members 144 and 146 can extend across the bottom of the crucible 124. Some of the bottom structural members 146 can be shaped such that they allow a forklift or other machine to lift or otherwise physically manipulate the apparatus.

### Method of Purifying Silicon

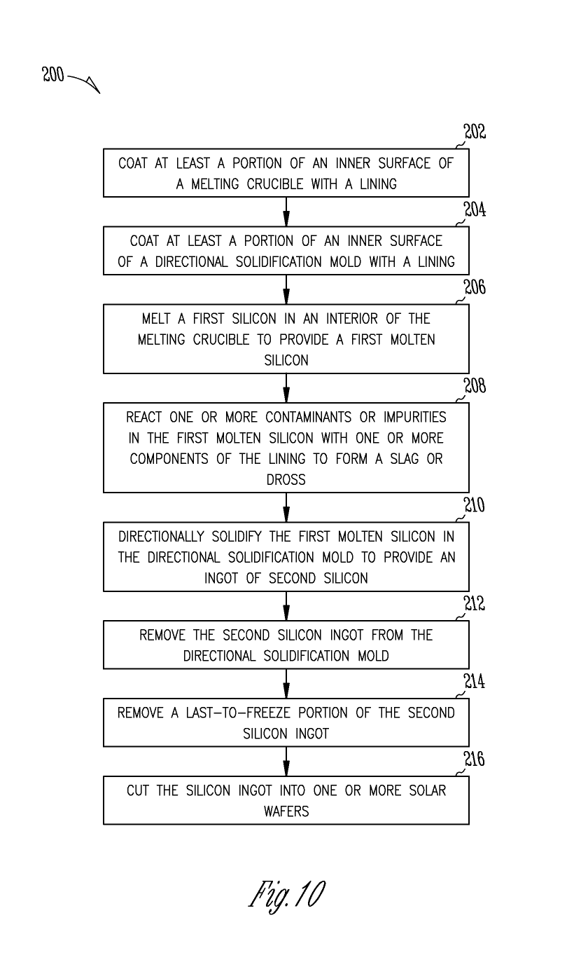

FIG. 10 is a flow diagram of an example method 200 for the purification of silicon. The method 200 can include, at 202, coating at least a portion of an inner surface of melting crucible with a lining. In an example, the lining that is coated onto the inner surface of the melting crucible includes a barrier layer comprising silicon carbide particles bound together by a colloidal silica binder, as described above with respect to FIGS. 1 and 2. In another example, the lining that is coated onto the inner surface of the melting crucible includes an active purification layer comprising a flux composition comprising a colloidal silica, such as the example lining described above with respect to FIGS. 3 and 4. The flux composition can also include one or more flux materials, including, but are not limited to, at least one of sodium carbonate (Na₂CO₃), calcium oxide (CaO), and calcium fluoride (CaF₂), such as the example lining described above with respect to FIG. 5. The lining that is coated onto the inner surface of the melting crucible can comprise both a barrier layer comprising silicon carbide particles bound together by a colloidal silica binder and an active purification layer comprising a colloidal silica, and optionally one or more flux materials, such as the lining described above with respect to FIGS. 6 and 7.

At 204, a lining can be coated onto at least a portion of an inner surface of a directional solidification mold. In an example, the lining that is coated onto the inner surface of the directional solidification mold includes a barrier layer comprising silicon carbide particles bound together by a colloidal silica binder, as described above with respect to FIGS. 1 and 2. In another example, the lining that is coated onto the inner surface of the directional solidification mold includes an active purification layer comprising a flux composition comprising a colloidal silica, such as the example lining described above with respect to FIGS. 3 and 4. The flux composition can also include one or more flux materials, including, but are not limited to, at least one of sodium carbonate (Na₂CO₃), calcium oxide (CaO), and calcium fluoride (CaF₂), such as the example lining described above with respect to FIG. 5. The lining that is coated onto the inner surface of the directional solidification mold can comprise both a barrier layer comprising silicon carbide particles bound together by a colloidal silica binder and an active purification layer comprising a colloidal silica, and optionally one or more flux materials, such as the lining described above with respect to FIGS. 6 and 7.

In some examples, only the inner surface of the melting crucible may be coated. In other examples, only the inner surface of the directional solidification mold may be coated. In still other examples, both the inner surface of the melting crucible and the inner surface of the directional solidification mold can be coated.

At 206, a first silicon can be melted in an interior of the melting crucible to provide a first molten silicon. The first silicon can include silicon of any suitable grade of purity. The first silicon can be at least partially melted. At least partially melting the first silicon can include completely melting the first silicon, almost completely melting the first silicon (over about either 99%, 95%, 90%, 85%, or 80% melted by weight), or partially melting the first silicon (less than about 80% or less melted by weight). The method can also include transferring the first molten silicon from the melting crucible to the directional solidification mold, such as by pouring the first molten silicon into the directional solidification mold.

At 208, if the lining that is coated onto the crucible is an active purification lining, then one or more contaminants or impurities in the first molten silicon can react with one or more components of the lining to form a slag or dross. In an example, the slag can form within the lining itself

At 210, the first molten silicon is directionally solidified in the direction solidification mold to provide an ingot comprising a second silicon. In an example, the first molten silicon can be solidified starting approximately at the bottom of the directional solidification mold, and approximately ending at the top of the directional solidification mold to form the second silicon. The directional solidification can cause the last-to-freeze portion of the second silicon to include a greater concentration of impurities than earlier frozen portions of the second silicon. The portions of the second silicon other than the last-to-freeze portion can include a lower concentration of impurities than the last-to-freeze portion of the second silicon. The second silicon can be a silicon ingot. The silicon ingot can suitable for cutting into solar wafers, e.g., for the manufacture of solar cells.

In an example, directional solidification can include positioning a top heater over the directional solidification mold. The directional solidification mold can be preheated before molten silicon is added. The top heater can be used to preheat the directional solidification mold. Preheating the directional solidification mold can help to prevent excessive quick solidification of silicon on the walls of the directional solidification mold. The top heater can be used to melt the first silicon to form the first molten silicon. The top heater can be used to transfer heat to the first molten silicon. The top heater can transfer heat to the first molten silicon when the silicon is melted in the directional solidification mold. The top heater can be used to control the heat of the top of the first molten silicon. The top heater can be used as an insulator, to control the amount of heat loss at the top of the directional solidification mold. The first silicon can be melted outside the apparatus, such as in a melting crucible in a furnace, and then added to the directional solidification mold. In some examples, silicon that is melted outside the apparatus can be further heated to a desired temperature using the top heater after being added to the directional solidification mold.

In an example, the top heater can include an induction heater, the silicon can be melted prior to being added to the directional solidification mold. Alternatively, the top heater can include heating elements as well as induction heaters. Induction heating can be more effective with molten silicon. Induction can cause mixing of the molten silicon. In some examples, the power can be adjusted sufficiently to optimize the amount of mixing, as too much mixing can improve segregation of impurities but can also create undesirable porosity in the final silicon ingot.

The directional solidification can include the removal of heat from the bottom of the directional solidification mold. The removal of heat can occur in any suitable fashion. For example, the removal of heat can include at least one of blowing fans across the bottom of the directional solidification mold, allowing ambient air to cool the bottom of the directional solidification mold with or without the use of fans, running a cooling liquid through tubes adjacent to the bottom of the apparatus, though tubes that run through the bottom of the apparatus, through tubes that run through a material on which the apparatus sits, or a combination thereof Removal of heat from the bottom of the directional solidification mold can allow a thermal gradient to be established in the directional solidification mold that can provide for better control of directional solidification of the first molten silicon approximately from the bottom of the directional solidification mold to the top of the directional solidification mold.

Removal of heat from the bottom of the directional solidification mold can be performed for the entire duration of the directional solidification. Multiple cooling methods can be used. For example, the bottom of the directional solidification mold can be liquid cooled and cooled with fans. Fan cooling can occur for part of the directional solidification, and liquid cooling for another, with any suitable amount of overlap or lack thereof between the two cooling methods. Cooling with liquid can occur for part of the directional solidification, and ambient air cooling alone for another part, with any suitable amount of overlap or lack thereof between the two cooling methods. Cooling by setting the directional solidification mold on a cooled block of material can also occur for any suitable duration of the directional solidification, including in any suitable combination with other cooling methods with any suitable amount of overlap. Cooling of the bottom of the directional solidification mold can be performed while heat is being added to the top; for example, while heat is added to the top to increase the temperature of the top, to maintain the temperature of the top, or to allow a particular rate of cooling of the top. All suitable configurations and methods of heating the top of the directional solidification mold, cooling the bottom of the directional solidification mold, and combinations thereof, with any suitable amount of temporal overlap or lack thereof, are encompassed as examples of the present invention.

The directional solidification can include using the top heater to heat the silicon to at least about 1200° C., and slowly cooling the temperature of the top of the silicon over from about 10 to about 16 hours. The directional solidification can include using the top heater to heat the silicon to between about 1200° C. and about 1600° C., inclusive, and holding the temperature of the top of the silicon approximately constant for about 14 hours. The directional solidification can include turning off the top heater, allowing the silicon to cool for from about 2 to about 60 hours, and then removing the top heater from the directional solidification mold.

At 212, the second silicon can be removed from the directional solidification mold. The silicon can be removed by any suitable method. For example, the silicon can be removed by inverting the directional solidification mold and allowing the second silicon to drop out of the directional solidification mold. In another example, the directional solidification apparatus can be separated into two or more portions, such as by being able to be parted substantially down the middle to form two halves, allowing the second silicon to be removed from the directional solidification mold.

At 214, a portion of the second silicon, e.g., the silicon ingot, can be removed. Preferably, the removal of the portion of the second silicon leads to an increase in the overall purity of a resulting silicon ingot. For example, the method can include removing from the directionally solidified second silicon at least part of the last-to-freeze section. The last-to-freeze section of the directionally solidified silicon can be the top of the second silicon ingot, as it is oriented during the bottom-to-top directional solidification. The greatest concentration of impurities can generally occur in the last-to-freeze section of the solidified silicon. Removing the last-to-freeze section thus can remove impurities from the solidified silicon, resulting in a trimmed-second silicon with a lower concentration of impurities than the first silicon. The removal of a portion of the silicon can include cutting the solid silicon with a band saw, a wire saw, or any suitable cutting device. The removal of a section of the silicon can include shot blasting or etching. Shot blasting or etching can also be used generally to clean or remove any outer surface of the second silicon, not just the last-to-freeze portion. The removal of a portion of the silicon can include removal of a last-to-freeze liquid portion, such as by pouring the remaining liquid from the crucible.

At 216, after removing the portion of the second silicon ingot, e.g., the last-to-freeze portion, the silicon ingot can be cut into one or more solar wafers using, for example, a band saw, a wire saw, or any suitable cutting device.

### Embodiments

To better illustrate the method and apparatuses disclosed herein, a non-limiting list of embodiments is provided here:

Embodiment 1 includes a crucible for containing a molten silicon mixture, the crucible including a body comprising at least one refractory material having at least one inner surface defining an interior for receiving molten silicon, and a lining deposited onto the inner surface, the lining comprising colloidal silica.

Embodiment 2 includes embodiment 1, wherein the lining further comprises at least one flux material capable of reacting with the molten silicon to form a slag.

Embodiment 3 includes any of embodiments 1-2, wherein the flux material comprises at least one of sodium carbonate, calcium oxide, and calcium fluoride.

Embodiment 4 includes any of embodiments 1-3, wherein the colloidal silica comprises silica particles suspended in a liquid phase, the silica particles have a size between 10 nanometers and 30 nanometers, inclusive.

Embodiment 5 includes any of embodiments 1-4, wherein the lining includes silicon carbide particles bound together by a colloidal silica.

Embodiment 6 includes any of embodiments 1-5, wherein the lining is 40%, by weight, silicon carbide and 60%, by weight, colloidal silica.

Embodiment 7 includes any of embodiments 1-6, wherein the silicon carbide particles have a size of less than or equal to about 3.5 millimeters.

Embodiment 8 includes any of embodiments 1-7, wherein the lining has a thickness of from 2 millimeters to 10 millimeters, inclusive.

Embodiment 9 includes any of embodiments 1-8, wherein the at least one refractory material comprises alumina.

Embodiment 10 includes any of embodiments 1-9, wherein the crucible is used to form a molten metal containing silicon.

Embodiment 11 includes any of embodiments 1-10, wherein the crucible is used as a mold for directional solidification.

Embodiment 12 includes a method for the purification of silicon, the method including melting a first silicon in an interior of a melting crucible to provide a first molten silicon, the melting crucible comprising a first refractory material having at least one first inner surface defining the interior of the melting crucible, directionally solidifying the first molten silicon in a directional solidification mold to provide a second silicon, the directional solidification mold comprising a second refractory material having at least one second inner surface defining an interior of the directional solidification mold, and coating at least a portion of at least one of the first inner surface and the second inner surface with a lining comprising colloidal silica.

Embodiment 13 includes embodiment 12, wherein coating at least a portion of at least one of the first inner surface and the second inner surface with the lining includes coating at least a portion of at least one of the first inner surface and the second inner surface with a lining that further includes silicon carbide particles.

Embodiment 14 includes any of embodiments 12-13, wherein coating at least a portion includes coating with a lining that is 40%, by weight, silicon carbide and 60%, by weight, colloidal silica.

Embodiment 15 includes any of embodiments 12-14, wherein coating at least a portion includes coating with a lining that includes silicon carbide particles with a size of less than or equal to about 3.5 millimeters.

Embodiment 16 includes any of embodiments 12-15, wherein coating at least a portion includes coating with a lining that includes silica particles suspended in a liquid phase, the silica particles have a size between 10 nanometers and 30 nanometers, inclusive.

Embodiment 17 includes any of embodiments 12-16, wherein coating at least a portion includes coating with a lining that has a thickness of between 2 millimeters and 10 millimeters, inclusive.

Embodiment 18 includes any of embodiments 12-17, wherein melting the first silicon in the interior of the melting crucible includes melting in a crucible wherein the first refractory material of the melting crucible comprises alumina.

Embodiment 19 includes any of embodiments 12-18, wherein directionally solidifying the first molten silicon in a directional solidification mold includes directionally solidifying in a mold wherein the second refractory material comprises alumina.

Embodiment 20 includes any of embodiments 12-19, wherein directionally solidifying the first molten silicon in a directional solidification mold includes directionally solidifying in a mold wherein the lining includes two layers including a passive inner layer and an active outer layer.

Embodiment 21 includes any of embodiments 12-20, wherein coating at least a portion of at least one of the first inner surface and the second inner surface with the lining comprises coating at least a portion of each of the first inner surface and at least a portion of the second inner surface with the lining.

### EXAMPLE

A melting crucible 10 comprising a refractory material 12 comprising alumina is coated with a lining 30 that is configured to prevent or reduce contamination of impurities from the refractory material 12 to a molten silicon 2 within the crucible 10. The lining 30 comprises silicon carbide particles 32 held together by a binder 34 formed from a colloidal silica. The SiC particles 32 are formed from the commercially-available silicon carbide sold under the trade name NANOTEK SiC, sold by Allied Mineral Products, Inc., or Columbus, Ohio, USA. The colloidal silica used to form the binder 34 is the commercially-available colloidal silica sold under the trade name BINDZIL 2040 by WesBond Corp., Wilmington, Del., USA. The SiC particles 32 and the colloidal silica binder 34 are mixed together in a weight ration of about 60 wt. % SiC particles 32 and about 40 wt. % silica.

The mixture of the SiC particles 32 and the colloidal silica binder 34 was coated onto an inner surface 20 of the crucible 10 by a painting or brushing method. Three coats of the mixture were coated onto the inner surface 20 and the three coats were allowed to air dry for about 6 hours. The resulting lining 30 had a thickness of from about 4 mm to about 5 mm.

The crucible 10 was used for melting silicon to form molten silicon 2 that was then poured into a directional solidification mold for purification of the molten silicon 2 via directional solidification (described above). A particular crucible 10 and lining 30 was used for between 1 to 4 castings of molten silicon 2 (e.g., 1 to 4 individual batches of melting solid silicon to form the molten silicon 2). In an example of a lining of a directional solidification mold, the lining 30 is refreshed after each directional solidification of an ingot. After the 1 to 4 castings, the lining 30 of the crucible 10 can be refreshed, such as by removing any remnants of the previous lining 30, followed by recoating a new lining 30 via the same coating and drying method described above.

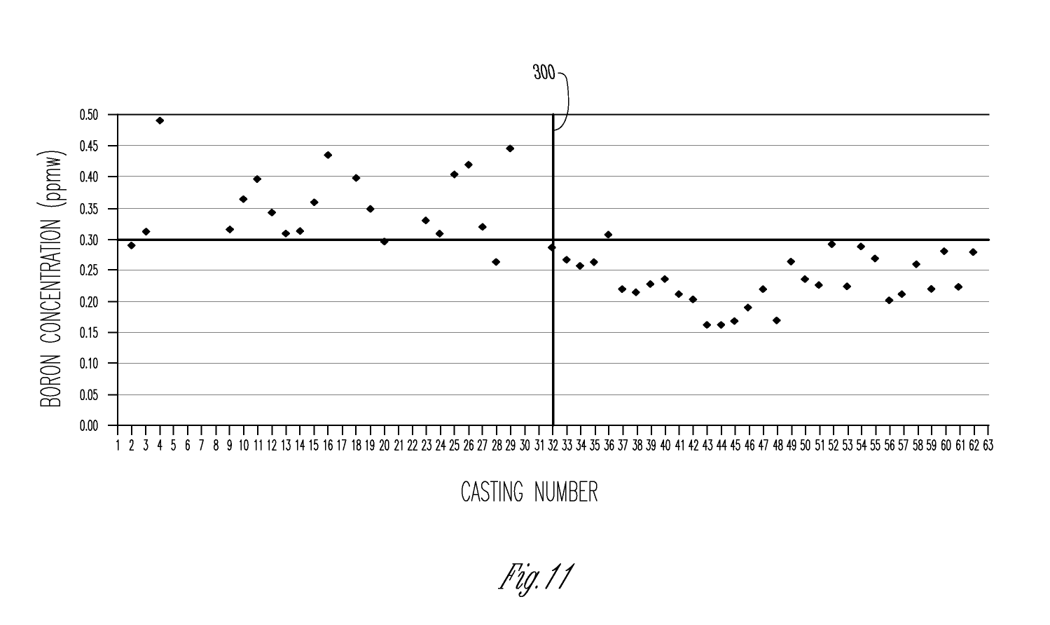

FIG. 11 shows an example of the level of a particular contaminant, in this case boron, within the silicon ingots that result after directional solidification using the crucible 10. FIG. 11 shows the boron concentration, in parts per million weight (ppmw), that was determined from individual melting and directional solidification runs, referred to herein as “castings.” The castings to the left of point 300 are the result of a melting crucible with no lining, e.g., where the molten silicon 2 can be in direct contact with the alumina refractor material. The boron level in the silicon that is being fed to the crucible 10 before being melted by the crucible 10 is known to be no more than about 0.25 ppmw boron. Therefore, if the boron level in the resulting silicon ingot is greater than 0.25 ppmw boron, then the increased boron is assumed to be coming from within the crucible 10, and most likely from the refractory material 12.

As shown in FIG. 11, the castings to the left of point 300 (e.g., those castings made from silicon melted in a melting crucible that did not include a barrier lining) generally have a boron level that is higher than 0.25 ppmw, and in most cases, greater than the 0.30 ppmw that is selected as an upper threshold for the boron level with a product silicon ingot. The castings to the right of point 300 (e.g., those castings made from silicon melted in a crucible 10 that did include a barrier lining 30) are essentially all below the 0.30 ppmw threshold, and most are below the 0.25 ppmw line. FIG. 11 shows that the lining 30 can act as a barrier to boron passing from the crucible 10 into the molten silicon 2. A similar chart showing the concentration of phosphorus within resulting silicon ingots revel that the lining 30 can act as a barrier to phosphorus passing from the crucible 10 into the molten silicon 2 as well.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,”

“B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A crucible for containing a molten silicon mixture, the crucible comprising:
a body comprising at least one refractory material having at least one inner surface defining an interior for receiving molten silicon; and
a lining deposited onto the inner surface, the lining comprising colloidal silica.

2. The crucible of claim 1, wherein the lining further comprises at least one flux material capable of reacting with the molten silicon to form a slag.

3. The crucible of claim 2, wherein the flux material comprises at least one of sodium carbonate, calcium oxide, and calcium fluoride.

4. The crucible of claim 1, wherein the colloidal silica comprises silica particles suspended in a liquid phase, the silica particles have a size between 10 nanometers and 30 nanometers, inclusive.

5. The crucible of claim 1, wherein the lining includes silicon carbide particles bound together by a colloidal silica.

6. The crucible of claim 4, wherein the lining is 40%, by weight, silicon carbide and 60%, by weight, colloidal silica.

7. The crucible of claim 4, wherein the silicon carbide particles have a size of less than or equal to about 3.5 millimeters.

8. The crucible of claim 1, wherein the lining has a thickness of from 2 millimeters to 10 millimeters, inclusive.

9. The crucible of claim 1, wherein the at least one refractory material comprises alumina.

10. The crucible of claim 1, wherein the crucible is used to form a molten metal containing silicon.

11. The crucible of claim 1, wherein the crucible is used as a mold for directional solidification.

12. A method for the purification of silicon, the method comprising:
melting a first silicon in an interior of a melting crucible to provide a first molten silicon, the melting crucible comprising a first refractory material having at least one first inner surface defining the interior of the melting crucible;
directionally solidifying the first molten silicon in a directional solidification mold to provide a second silicon, the directional solidification mold comprising a second refractory material having at least one second inner surface defining an interior of the directional solidification mold; and
coating at least a portion of at least one of the first inner surface and the second inner surface with a lining comprising colloidal silica.

13. The method of claim 12, wherein coating at least a portion of at least one of the first inner surface and the second inner surface with the lining includes coating at least a portion of at least one of the first inner surface and the second inner surface with a lining that further includes silicon carbide particles.

14. The method of claim 13, wherein coating at least a portion includes coating with a lining that is 40%, by weight, silicon carbide and 60%, by weight, colloidal silica.

15. The method of claim 13, wherein coating at least a portion includes coating with a lining that includes silicon carbide particles with a size of less than or equal to about 3.5 millimeters.

16. The method of claim 12, wherein coating at least a portion includes coating with a lining that includes silica particles suspended in a liquid phase, the silica particles have a size between 10 nanometers and 30 nanometers, inclusive.

17. The method of claim 12, wherein coating at least a portion includes coating with a lining that has a thickness of between 2 millimeters and 10 millimeters, inclusive.

18. The method of claim 12, wherein melting the first silicon in the interior of the melting crucible includes melting in a crucible wherein the first refractory material of the melting crucible comprises alumina.

19. The method of claim 12, wherein directionally solidifying the first molten silicon in a directional solidification mold includes directionally solidifying in a mold wherein the second refractory material comprises alumina.

20. The method of claim 12, wherein directionally solidifying the first molten silicon in a directional solidification mold includes directionally solidifying in a mold wherein the lining includes two layers including a passive inner layer and an active outer layer.

21. (canceled)
